(19) United States
(12) Patent Application Publication
(10) Pub. No.: US 2019/0004424 A1
(43) Pub. Date: Jan. 3, 2019

(54) THERMALLY CONDUCTIVE TYPE PHOTOSENSITIVE RESIN

(71) Applicant: Microcosm Technology Co., Ltd, Tainan City (TW)

(72) Inventors: Tang-Chieh Huang, Tainan City (TW); Wei-Chung Chuang, Tainan City (TW)

(73) Assignee: Microcosm Technology Co., Ltd

(21) Appl. No.: 15/933,031

(22) Filed: Mar. 22, 2018

(30) Foreign Application Priority Data
Jun. 30, 2017 (TW) 106121970

(51) Int. Cl. G03F 7/038; C08L 79/08; C08L 83/10; C08K 5/00; C08K 5/13; C08L 63/00

(52) U.S. Cl. CPC G03F 7/0387; C08L 79/08; C08L 83/10; C08L 67/02; C08K 5/13; C08L 63/00; C08K 5/0025

(57) ABSTRACT

A thermally conductive type photosensitive resin is provided. The resin comprises (a) a photosensitive polyimide, (b) an inorganic filler, and (c) a silica solution. The photosensitive polyimide accounts for 50 to 80% of a total weight of a solid composition of the thermally conductive type photosensitive resin. The inorganic filler is selected from at least one of aluminium oxide, graphene, inorganic clay, mica powder, boron nitride, aluminium nitride, silica, zinc oxide, zirconium oxide, carbon nanotube and carbon nanofiber, accounts for 20-50% of the total weight of the solid composition of the thermally conductive type photosensitive resin, and has a particle size between 40 nm and 5 μm. The silica solution comprises silica particles polymerized by a sol-gel process. The silica particles have a particle size between 10 nm and 15 nm, and account for 5 to 30% of the total weight of the solid composition of the thermally conductive type photosensitive resin. The thermally conductive type photosensitive resin has a thermal conductivity between 0.4 and 2.

### BACKGROUND OF THE INVENTION

### Field of the Invention

The present invention discloses a thermally conductive type photosensitive resin, and more particularly relates to a thermally conductive type photosensitive resin having a photosensitive polyimide as the main component.

### Description of the Prior Art

In general, the polyimide resin is prepared from the condensation polymerization of an aromatic tetracarboxylic acid or a derivative thereof with an aromatic diamine or an aromatic diisocyanate. The resulting polyimide resin has excellent heat resistance, chemical resistance, and mechanical and electrical properties, and therefore is widely used in insulating and heat-resistant electronic materials, such as semiconductor sealants.

It is often necessary to form line patterns by using micro lithography when polyimide is applied to the process of semiconductor components. If a conventional polyimide is used, a layer of photoresist must be added additionally for etching. Therefore, since the photosensitive polyimide (PSPI) has both the properties of photoresist and insulation protection materials that can simplify the process and make considerable progress in the flexible panel electronic material process, it is currently a quite popular and advanced material.

However, due to the increasingly intensive circuit design in recent years, the heat generated in the circuit accumulates, resulting in overheating of the product, which becomes an urgent problem to be solved. The demand for photosensitive polyimide with good thermal conductivity begins to come to light. Generally, the photosensitive polyimide has a thermal conductivity of about 0.1-0.2. Traditionally, the method to improve the thermal conductive ability of polyimide is adding filler to increase the contact area. However, increasing the contact area will simultaneously make light uneasy to pass through, which will contrarily reduce the resolution of light sensitizing.

### SUMMARY OF THE INVENTION

The object of the present invention is to solve the problem of photosensitivity reduction of the thermally conductive type photosensitive resin described above, and to provide a thermally conductive type photosensitive resin having a high thermal conductivity and a good photosensitivity.

According to an embodiment of the present invention, a thermally conductive type photosensitive resin is provided. The resin comprises (a) a photosensitive polyimide, (b) an inorganic filler, and (c) a silica solution. The photosensitive polyimide is a polymer or a copolymer composed of a repeating unit of formula (1) below:

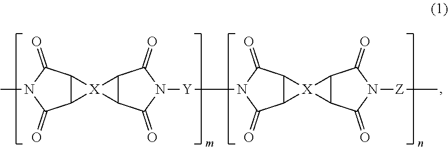

wherein m and n are each independently 10 to 600; X is a tetravalent organic group, whose main chain moiety contains an alicyclic compound group, which accounts for 60-80% of the total composition; Y is a divalent organic group, whose main chain moiety contains a polydimethylsiloxane group; and Z is a divalent organic group, whose branched moiety contains at least a phenoilc hydroxyl group or a carboxyl group. The photosensitive polyimide accounts for 50 to 80% of a total weight of a solid composition of the thermally conductive type photosensitive resin.

The inorganic filler is selected from at least one of aluminium oxide, graphene, inorganic clay, mica powder, boron nitride, aluminium nitride, silica, zinc oxide, zirconium oxide, carbon nanotube and carbon nanofiber, accounts for 20-50% of the total weight of the solid composition of the thermally conductive type photosensitive resin, and has a particle size between 40 nm and 5 μm.

The silica solution comprises silica particles polymerized by a sol-gel process, wherein the silica particles have a particle size between 10 nm and 15 nm, and account for 5 to 30% of the total weight of the solid composition of the thermally conductive type photosensitive resin. The thermally conductive type photosensitive resin has a thermal conductivity between 0.4 and 2.

In an embodiment, the thermally conductive type photosensitive resin described above further includes an acrylic resin photo-crosslinking agent. The acrylic resin accounts for 5 to 40% of the total weight of the solid composition of the thermally conductive type photosensitive resin.

In an embodiment, the thermally conductive type photosensitive resin described above further includes a thermal crosslinking agent. The thermal crosslinking agent includes a phenolic compound, an alkoxymethylamine resin, or an epoxy resin, and accounts for 5 to 40% of the total weight of the solid composition of the thermally conductive type photosensitive resin.

In an embodiment, the inorganic filler is boron nitride or aluminum nitride.

In an embodiment, X in the photosensitive polyimide of formula (1) is one of the following groups:

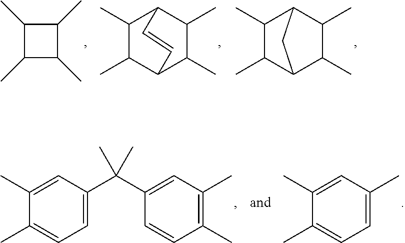

In an embodiment, Y in the photosensitive polyimide of formula (1) is the following group:

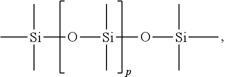

in which p=0-20.

In an embodiment, Z in the photosensitive polyimide of formula (1) is one of the following groups:

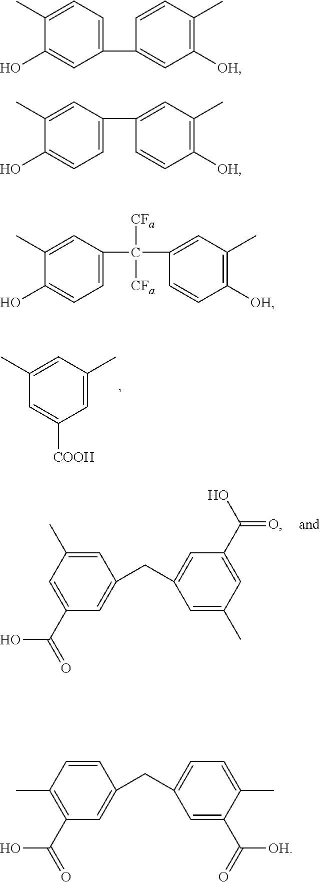

In an embodiment, the silica particles in the silica solution account for 7.5 to 15% of the total weight of the solid composition of the thermally conductive type photosensitive resin and have a particle size of 10-15 nm.

The foregoing and other aspects of the present invention will become more apparent from the following detailed description of the embodiments. It is to be particularly noted that the compositions and formulations of the embodiments are only exemplary and are not intended to limit the invention.

### DETAILED DESCRIPTION OF THE EMBODIMENTS

The present invention provides a thermally conductive type photosensitive resin, the main component of which is a photosensitive polyimide having a specific molecular structure. By adding the inorganic filler to improve the thermal conductivity and further adding the silica solution to enhance the light penetration effect, the polyimide resin with high thermal conductivity and excellent photosensitivity is obtained.

The thermally conductive type photosensitive resin of the present invention comprises (a) a photosensitive polyimide, (b) an inorganic filler, and (c) a silica solution. The photosensitive polyimide (a) has a structure of formula (1) below:

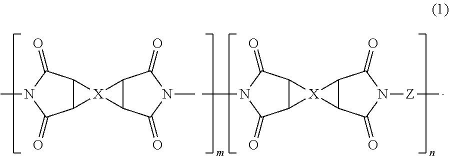

In formula (1), m and n are each independently 10 to 600. X is a tetravalent organic group, a main chain moiety of which contains an alicyclic compound group, including (but not limited to) the following groups or a combination thereof:

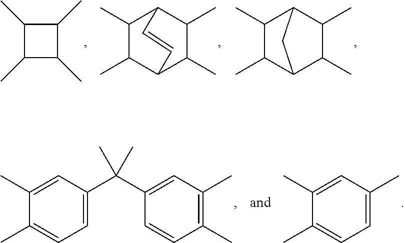

Y is a divalent organic group, preferably containing (but not limited to) the following groups:

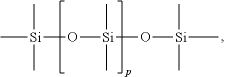

in which p=0-20.

The chain length of Y is preferably short (p=0), and the longest chain length of Y may be p=20. If the chain length is too long, the nature of the photosensitive polyimide will be destroyed.

Z is a divalent organic group, a side chain of which may contain a phenolic hydroxyl group or a carboxyl group. The content of the phenolic hydroxyl group or the carboxyl group approximately accounts for 10 to 30% of the number of moles of the polyimide. The development time may be controlled by adjusting the content of the branched phenolic hydroxyl group or the carboxyl group. When the content of the branched phenolic hydroxyl group or carboxyl group is high, the alkaline developer is preferred for the solubility of the photosensitive polyimide and may improve the developability.

Z may include, but not be limited to, the following groups:

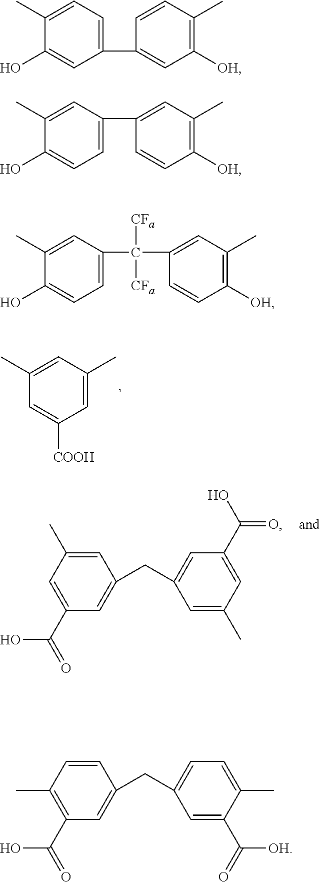

The photosensitive polyimide (a) preferably accounts for 50 to 80% of the total weight of the solid composition of the thermally conductive type photosensitive resin.

The thermally conductive type photosensitive resin of the present invention further comprises (b) an inorganic filler for the main purpose of improving the thermal conductivity of polyimide resin. The inorganic filler may be selected from one or more of aluminium oxide, graphene, inorganic clay, mica powder, boron nitride, silica, aluminium nitride, zinc oxide, zirconium oxide, carbon nanotube and carbon nanofiber, and preferably has a particle size between 40 nm and 5 μm. The inorganic filler preferably accounts for 20-50% of the total weight of the solid composition of the thermally conductive type photosensitive resin.

In addition, a silica solution (colloidal silica) (c) is further added to the thermally conductive type photosensitive resin of the present invention. The silica solution comprises the nanosized silica particles polymerized by the sol-gel method, such as DMAC-ST from Nissan Chemical. The silica particles have a particle size of 10-15 nm. The silica particles in the silica solution preferably accounts for 5 to 30% of the total weight of the solid composition of the thermally conductive type photosensitive resin. In the invention, through adding two kinds of fillers with different particle sizes, the inorganic filler with a relatively large particle size is separated by the silica particles with a smaller particle size such that the interior of the colloid is not masked by the thermally conductive inorganic filler with a relatively large particle size when it is exposed to light, which maintains the resolution of the photosensitive polyimide while the thermally conductive ability is improved.

The thermally conductive type photosensitive resin of the present invention may additionally contain a thermal crosslinking agent with a structure having a phenolic compound or an alkoxymethylamine resin so that the terminal group on the molecular chain of the polyimide form a crosslinked structure with the thermal crosslinking agent during exposure and baking. The acrylic resin photocrosslinking agent can also be added to generate acid after exposure and form an acid-catalyzed crosslinking mechanism. The crosslinked structure thus produced can increase the chemical resistance and film-forming properties of the thermally conductive type photosensitive resin.

The main purpose of the thermal crosslinking agent is to crosslink with the PI backbone-OH group or the ortho position of the terminal-OH group via acid catalysis and heat treatment during hard baking after exposure such that there exists a solubility difference between the exposed and non-exposed areas for facilitating the quick formation of patterns. The amount of the thermal crosslinking agent is about 5-40% of the total weight of the solid composition of the thermally conductive type photosensitive resin. If the amount is less than 5%, the crosslinking will be insufficient and the resin won't be resistant to chemical solvents. If the amount exceeds 40%, the developability will be poor.

After exposure and absorption of a certain wavelength of light, the photo-crosslinking agent will generate free radicals to initiate or catalyze the polymerization of the corresponding monomers or prepolymers in order to form crosslinks. The addition amount of the photo-crosslinking agent is 5 to 40% of the total weight of the solid composition of the thermally conductive type photosensitive resin. If it is less than 5%, the photosensitivity is insufficient; and if it exceeds 40%, the developability is poor.

The synthesis steps of the photosensitive polyimide were carried out by dissolving appropriate amounts of the diamine monomer and the dianhydride monomer in 1-Methyl-2-pyrrolidone (NMP), followed by reacting at 80° C. for 2 hours, followed by addition of xylene and heating to 180° C. for distillating. The diamine monomer containing the phenolic hydroxyl group or carboxyl group was further added, followed by reacting at 80° C. for 2 hours, followed by addition of xylene and heating to 180° C. for distillating, and followed by cooling after approximately 4 hours. The method for preparing the thermally conductive type photosensitive resin was carried out by taking the photosensitive polyimide colloid prepared above and then adding the inorganic filler, the silica solution, the photo-crosslinking agent and the thermal crosslinking agent thereto for obtaining the thermally conductive type photosensitive resin of the present invention. (The photo-crosslinking agent and the thermal crosslinking agent may be added optionally.)

### Example 1

19.88 g (80 mmol) of 1,3-bis(3-aminopropyl)-1,1,3,3-tetramethyldisiloxane, 80.7 g of 1-methyl-2-pyrrolidone (NMP), and 39.68 g (160 mmol) of bicyclo[2,2,2]oct-7-ene-2,3,5,6-tetracarboxylic dianhydride were added into a 500 ml three-necked round bottom flask equipped with the mechanical stirrer and nitrogen inlet to form a solution. The solution was reacted at 50 to 80° C. for 2 hours. Afterwards, 45 g of xylene was added and then the temperature was risen to 180° C. The mixture was kept stirring for 1.5 hours, and then 21.14 g (80 mmol) of 2-(methacryloyloxy)ethyl 3,5-diaminobenzoate was added. The resulting solution was reacted at 50 to 80° C. for 2 hours, and then 50 g of xylene was added and the temperature was risen to 180° C. The mixture was kept stirring for 4 hours and then cooled to give a PIA-1 solution. 11.38 g of glycidyl methacrylate (GMA) was added into 50 g of the PIA-1 solution, which was then stirred at 70 to 100° C. for 24 hours to give the photosensitive polyimide PSPI-1 of formula (1).

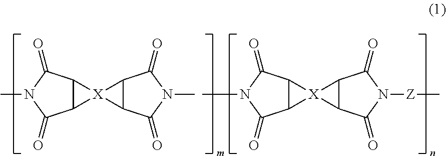

In the PSPI-1 of formula (1), X is

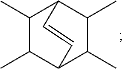

### Y is

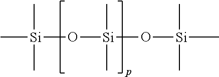

and p=0; Z is

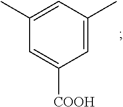

and m n 120.

9.375 g of the filler (1 μm boron nitride) and then 23.43 g of 20% silica solution (DMAC-ST from Nissan Chemical, the silica particles of which have a particle size of 10-15 nm) were added sequentially into 75 g of PSPI-1 and mixed uniformly to obtain the thermally conductive type photosensitive resin PSPI-BN1. PSPI-BN1 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (having a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

### Example 2

12.5 g of the filler (1 μm boron nitride) and then 25 g of 20% silica solution (having a particle size of 10-15 nm) were added sequentially into the PSPI-1 solution of Example 1 and mixed uniformly to obtain the thermally conductive type photosensitive resin PSPI-BN2. PSPI-BN2 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (having a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

### Example 3

16.07 g of the filler (1 μm boron nitride) and then 26.78 g of 20% silica solution (having a particle size of 10-15 nm) were added sequentially into the PSPI-1 solution of Example 1 and mixed uniformly to obtain the thermally conductive type photosensitive resin PSPI-BN3. PSPI-BN3 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (having a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

### Example 4

16.07 g of the filler (50 nm boron nitride) and then 26.78 g of 20% silica solution (having a particle size of 10-15 nm) were added sequentially into the PSPI-1 solution of Example 1 and mixed uniformly to obtain the thermally conductive type photosensitive resin PSPI-BN4. PSPI-BN4 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (having a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

### Example 5

12.5 g of the filler (5 μm aluminium nitride) and then 25 g of 20% silica solution (having a particle size of 10-15 nm) were added sequentially into the PSPI-1 solution of Example 1 and mixed uniformly to obtain the thermally conductive type photosensitive resin PSPI-BN5. PSPI-BN5 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (having a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

### Comparative Example 1

9.375 g of the filler (1 μm boron nitride) was added into the PSPI-1 solution of Example 1 and mixed uniformly to obtain the thermally conductive type photosensitive resin PSPI-CT1. PSPI-CT1 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (having a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

### Comparative Example 2

12.5 g of the filler (1 μm boron nitride) was added into the PSPI-1 solution of Example 1 and mixed uniformly to obtain the thermally conductive type photosensitive resin PSPI-CT2. PSPI-CT2 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (having a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

### Comparative Example 3

16.07 g of the filler (1 μm boron nitride) was added into the PSPI-1 solution of Example 1 and mixed uniformly to obtain the thermally conductive type photosensitive resin PSPI-CT3. PSPI-CT3 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (having a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

### Comparative Example 4

16.07 g of the filler (50 nm boron nitride) was added into the PSPI-1 solution of Example 1 and mixed uniformly to obtain the thermally conductive type photosensitive resin PSPI-CT4. PSPI-CT4 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (having a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

The formulations and properties of the thermally conductive type photosensitive resins of Examples 1-5 and Comparative Examples 1-4 are shown in Table 1:

TABLE 1
Measurements and comparisons of the properties of the thermally
conductive type photosensitive resin

| Thermally | | | | | | | | |
|---|---|---|---|---|---|---|---|---|
| conductive | | | | | Percentage | | | |
| type | Percentage | | Percentage | Particle | of silica | | | |
| photosensitive | of PSPI | Inorganic | of inorganic | size | particles | Thermal | Thermal | Resolution* |
| resin | (wt %) | filler | filler (wt %) | (nm) | (wt %) | conductivity | resistance | (μm) |
| Example 1 | 70 | boron | 20 | 1000 | 10 | 0.467 | 2.6 | 50 |
| | | nitride | | | | | | |
| Comparative | 80 | boron | 20 | 1000 | 0 | 0.45 | 2.62 | 100 |
| Example 1 | | nitride | | | | | | |
| Example 2 | 65 | boron | 25 | 1000 | 10 | 0.513 | 1.73 | 50 |
| | | nitride | | | | | | |
| Comparative | 75 | boron | 25 | 1000 | 0 | 0.499 | 1.84 | 100 |
| Example 2 | | nitride | | | | | | |
| Example 3 | 60 | boron | 30 | 1000 | 10 | 0.621 | 1.62 | 75 |
| | | nitride | | | | | | |
| Comparative | 70 | boron | 30 | 1000 | 0 | 0.615 | 1.65 | X |
| Example 3 | | nitride | | | | | | |
| Example 4 | 60 | boron | 30 | 50 | 10 | 0.411 | 2.3 | 75 |
| | | nitride | | | | | | |
| Comparative | 70 | boron | 30 | 50 | 0 | 0.19 | 2.3 | X |
| Example 4 | | nitride | | | | | | |
| Example 5 | 65 | aluminium | 25 | 5000 | 10 | 0.401 | 2.41 | 75 |
| | | nitride | | | | | | |

*Resolution means the minimum pattern size that can be achieved and repeated, and a smaller value is preferred.
*All the percentage refer to the weight percentage in the “solid composition” of the thermally conductive type photosensitive resin.

In table 1, percentage of filler refers to the percentage of the weight of the inorganic filler in the solid composition of the thermally conductive type photosensitive resin, and was calculated as the following formula:

%_{filler}=(W_{filler}/W_{solid})×100%

The measurement method of the solid percentage (%_{solid}) is carried out by taking and weighing an appropriate weight of colloid, baking at 200° C. for 90 minutes, and then weighing again after baking to obtain the weight of the solid composition (W_{solid}). After the weight of the solid composition is known, the solid percentage can be obtained by calculation using the following formula:

%_{solid}=(W_{solid}/Wₜₒₜₐₗ)×100%

Taking the thermally conductive type photosensitive resin PSPI-BN2 of Example 2 for example, it was formed by adding 12.5 g of the inorganic filler-boron nitride into 75 g of the polyimide PSPI-1 (having a solid percentage of 50%), and thus percentage of the inorganic filler

$$( {\% }_{filler} ) = \frac{12.5}{75 \times 50 \% + 12.5} = 25 \%$$

The thermally conductive type photosensitive resin compositions of Examples 1-4 of the present invention are formed by adding different weight percentages (wt %) of the inorganic filler into the same photosensitive polyimide, with the addition of the same weight percentage of nanosized silica particles (in the form of a silica solution). In contrast, in Comparative Examples 1-4, different weight percentages (wt %) of the inorganic filler are added respectively into the same photosensitive polyimide without the addition of the silica solution. From Table 1 it is known that Examples 1-4, which include the silica solution and have fillers with different particle sizes, show better thermal conductivity, thermal resistance (the smaller is preferred), and resolution performance (the smaller is preferred), as compared with Comparative Examples 1-4 having only single kind of inorganic filler. At the even worse, Comparative Example 3 has no developability at all due to the addition of only one kind of inorganic filler as well as the excessive addition ratio, though the main component is also the photosensitive polyimide. Moreover, although the inorganic filler having a smaller particle size (50 nm) is used, Comparative Example 4 still has no developability due to the excessive addition ratio of the inorganic filler as well as no addition of the silica solution. Both the thermal conductivity and the thermal resistance are also worse. Example 5 uses another kind of the inorganic filler (aluminum nitride) to mix with the silica solution, which equally obtains the effect of high thermal conductivity, low thermal resistance, and excellent resolution. In the invention, through adding the inorganic filler with a relatively large particle size and the silica solution having the silica particles with a smaller particle size, the inorganic filler with a relatively large particle size is separated by the silica particles with a smaller particle size such that the interior of the colloid is not masked by the thermally conductive inorganic filler with a relatively large particle size when it is exposed to light, thereby obtaining the thermally conductive type photosensitive resin having a high thermal conductivity and excellent photosensitivity.

While the present invention is illustrated above by the embodiments, these embodiments are not intended to limit the invention. Equivalent implementations or alterations may be made to these embodiments by those skilled in the art without departing from the spirit of the art of the invention, and the scope of the present invention should be defined by the appended claims.

What is claimed is:

1. A thermally conductive type photosensitive resin, comprising:
(a) a photosensitive polyimide, being a polymer or a copolymer composed of a repeating unit of formula (1) below: 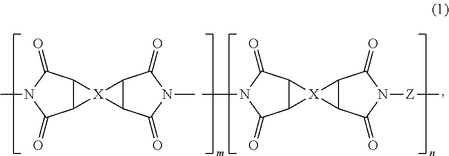
wherein m and n are each independently 10 to 600; X is tetravalent organic group, whose main chain moiety contains an alicyclic compound group; Y is a divalent organic group, whose main chain moiety contains a polydimethylsiloxane group; Z is a divalent organic group, whose branched moiety contains at least a phenoilc hydroxyl group or a carboxyl group, and the photosensitive polyimide accounts for 50 to 70% of a total weight of a solid composition of the thermally conductive type photosensitive resin;
(b) an inorganic filler selected from at least one of aluminium oxide, graphene, inorganic clay, mica powder, boron nitride, aluminium nitride, silica, zinc oxide, zirconium oxide, carbon nanotube and carbon nanofiber, accounting for 20-30% of the total weight of the solid composition of the thermally conductive type photosensitive resin, and having a particle size between 40 nm and 5 μm; and
(c) a silica solution comprising silica particles polymerized by a sol-gel process, wherein the silica particles have a particle size between 10 nm and 15 nm, and account for 5 to 30% of the total weight of the solid composition of the thermally conductive type photosensitive resin;
wherein the thermally conductive type photosensitive resin has a thermal conductivity between 0.4 and 2.

2. The thermally conductive type photosensitive resin of claim 1, further including a photo-crosslinking agent containing an acrylic resin.

3. The thermally conductive type photosensitive resin of claim 2, wherein the acrylic resin accounts for 5% of the total weight of the solid composition of the thermally conductive type photosensitive resin.

4. The thermally conductive type photosensitive resin of claim 1, further including a thermal crosslinking agent, which includes a phenolic compound, an alkoxymethylamine resin, or an epoxy resin.

5. The thermally conductive type photosensitive resin of claim 4, wherein the thermal crosslinking agent accounts for 5% of the total weight of the solid composition of the thermally conductive type photosensitive resin.

6. The thermally conductive type photosensitive resin of claim 1, wherein the inorganic filler is boron nitride or aluminum nitride.

7. The thermally conductive type photosensitive resin of claim 1, wherein X is one of the following groups:

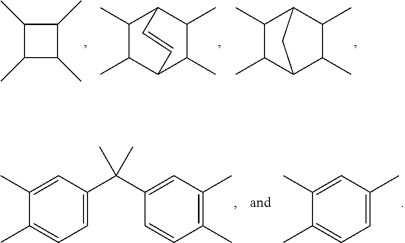

8. The thermally conductive type photosensitive resin of claim 1, wherein Y is the following group: 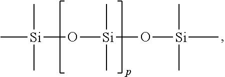
in which p=0-20.

9. The thermally conductive type photosensitive resin of claim 1, wherein Z is one of the following groups:

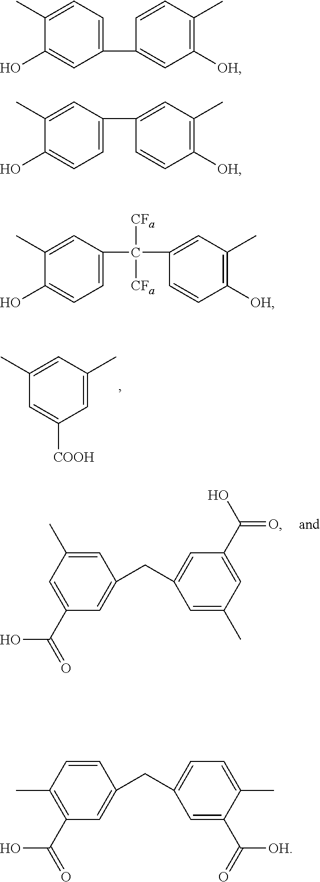

10. The thermally conductive type photosensitive resin of claim 1, wherein the silica particles account for 7.5 to 15% of the total weight of the solid composition of the thermally conductive type photosensitive resin and have a particle size of 10-15 nm.
